(19) United States
(12) Patent Application Publication
(10) Pub. No.: US 2010/0230826 A1
(43) Pub. Date: Sep. 16, 2010

(54) INTEGRATED CIRCUIT PACKAGE ASSEMBLY AND PACKAGING METHOD THEREOF

(75) Inventor: CHING-YAO FU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/507,154

(22) Filed: Jul. 22, 2009

(30) Foreign Application Priority Data
Mar. 12, 2009 (CN) 200910106126.6

(51) Int. Cl. H01L 23/485; H01L 21/50

(52) U.S. Cl. 257/777; 438/124; 257/E23.02; 257/E21.499

(57) ABSTRACT

An integrated circuit (IC) package assembly includes a substrate including a plurality of golden fingers, a bonding pad integrally formed with the substrate, an IC fixed on the bonding pad, and a plurality of bonding wires. The IC includes a plurality of connecting pads. A width and a length of the IC are greater than a width and a length of the bonding pad. The plurality of bonding wires electrically connect the plurality of connecting pads to the plurality of golden fingers.

### BACKGROUND

1. Technical Field

The present disclosure relates to semiconductor packages, and more particularly to an integrated circuit (IC) package assembly and packaging method.

2. Description of Related Art

Due to rapid developments in electronic technology, electronic products have been drastically reduced in size, resulting in a requirement for small integrated circuits (ICs) for application therein. In response, IC packages have been reduced in size.

FIG. 4 is a cross-sectional view of a commonly used IC package assembly 500. The IC package assembly 500 includes a substrate 510 including a plurality of golden fingers 512, a bonding pad 520, an IC 530 including a plurality of connecting pads 532, a plurality of bonding wires 540, and adhesive 550. A width and a length of the bonding pad 520 are greater than a width and a length of the IC 530. During assembly, the bonding pad 520 is disposed on a surface of the substrate 510 using the adhesive 550, and the IC 530 is fixed on the bonding pad 520 using the adhesive 550 with the plurality of bonding wires 540 electrically connecting the plurality of connecting pads 532 to the plurality of golden fingers 512.

However, because the width and length of the bonding pad 520 are greater than the width and length of the IC 530, the adhesive 550 is prone to overflow onto the plurality of connecting pads 532 of the IC 530, inflicting damage thereon.

### BRIEF DESCRIPTION OF THE DRAWINGS

FIG. 1 is a cross-sectional view of a first embodiment of an integrated circuit (IC) package assembly in accordance with the present disclosure;

FIG. 2 is a cross-sectional view of a second embodiment of an integrated circuit (IC) package assembly in accordance with the present disclosure;

FIG. 3 is a flowchart of an IC packaging method in accordance with the present disclosure; and

FIG. 4 is a cross-sectional view of a commonly used IC package assembly.

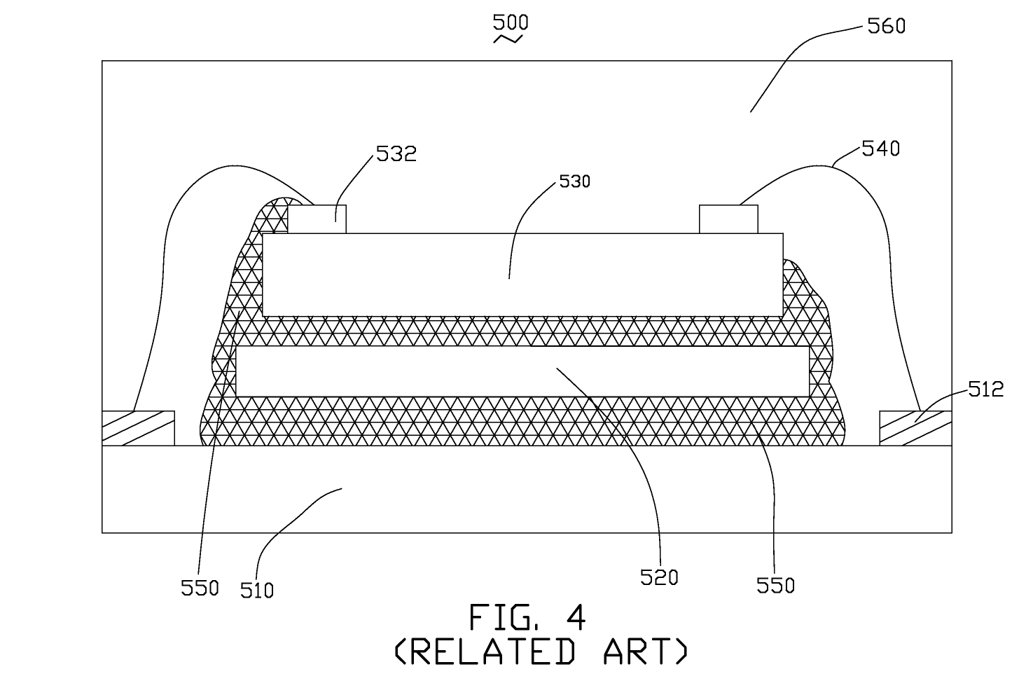

### DETAILED DESCRIPTION

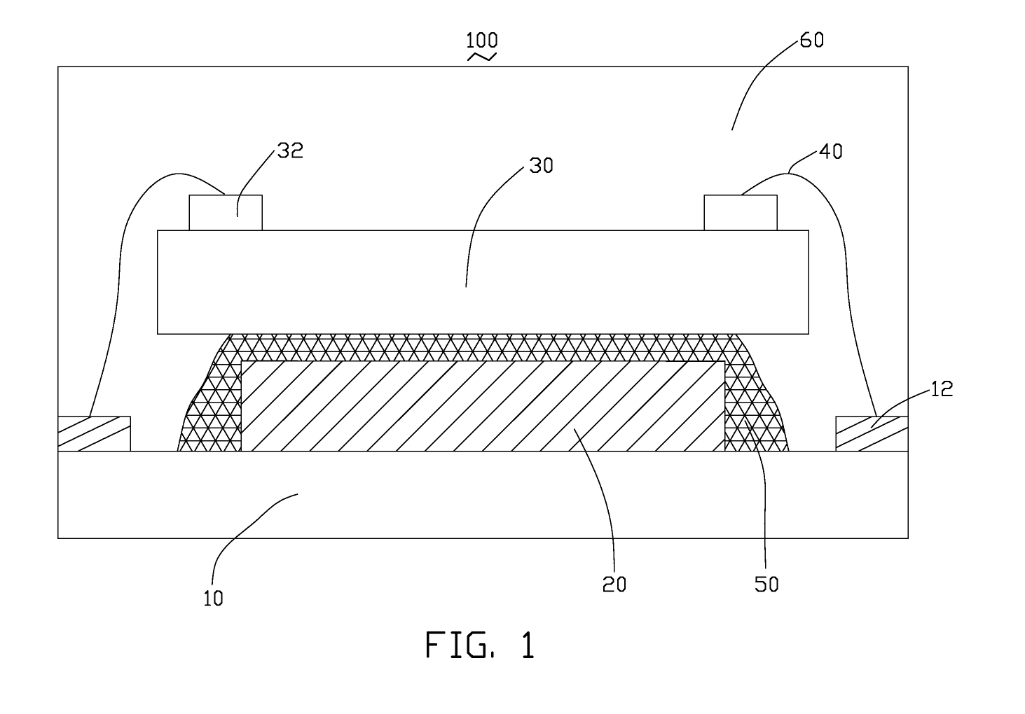

FIG. 1 is a cross-sectional view of a first embodiment of an integrated circuit (IC) package assembly 100 in accordance with the present disclosure. The IC package assembly 100 includes a substrate 10, a bonding pad 20, an IC 30, a plurality of bonding wires 40, and adhesive 50.

The substrate 10 is a printed circuit board, in one example, and includes a plurality of golden fingers 12 arranged on a surface thereof. In the illustrated embodiment, the plurality of golden fingers 12 are plated on the surface of the substrate 10.

The bonding pad 20 is integrally formed with the substrate 10. A thickness of the bonding pad 20 is greater than a thickness of each of the plurality of golden fingers 12, and a width and a length of the bonding pad 20 are less than a width and a length of the IC 30. In the illustrated embodiment, the bonding pad 20 is conductive, and plated on the surface of the substrate 10. That is, the bonding pad 20 and the plurality of golden fingers 12 are plated on the surface of the substrate 10, conserving assembly and disassembly cost of the bonding pad 20.

The IC 30 includes a plurality of connecting pads 32. The plurality of bonding wires 40 electrically connect the plurality of connecting pads 32 to the plurality of golden fingers 12 so that the IC 30 is electrically connected to the substrate 10. In the illustrated embodiment, a thickness of the IC 30 is less than or equal to 50 μm.

The IC 30 is fixed on the bonding pad 20 by the adhesive 50. In the illustrated embodiment, the adhesive 50 may be an epoxy resin to further provide improved heat dissipation of the IC 30.

The IC package assembly 100 further includes an encapsulation 60 disposed on the substrate 10 to encapsulate the IC 30, the bonding pad 20, the plurality of bonding wires 40, and the plurality of golden fingers 12 therein.

Because the width and length of the bonding pad 20 are less than the width and length of the IC 30, no overflow of the adhesive 50 affects the plurality of connecting pads 32 of the IC 30, thus avoiding damage thereto.

Because the bonding pad 20 is thicker than each of the plurality of golden fingers 12 and is not fixed to the substrate 10 by the adhesive 50, substantially less adhesive 50 flows onto the plurality of golden fingers 12, thus further avoiding damage thereto.

Because the bonding pad 20 is plated on the surface of the substrate 10, the bonding pad 20 cannot separate from the substrate 10 when the IC package assembly 100 undergoes a reflow procedure.

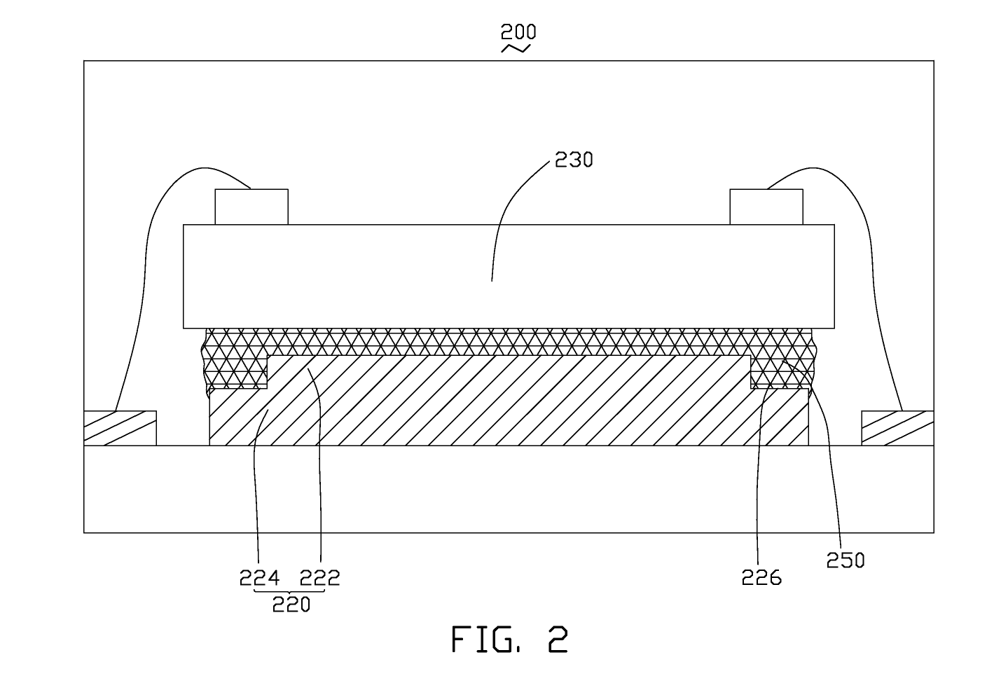

FIG. 2 is a cross-sectional view of a second embodiment of an integrated circuit (IC) package assembly 200 in accordance with the present disclosure, differing from the IC package assembly 100 shown in FIG. 1 in that the IC package assembly 200 includes a bonding pad 220 including a first pad 222, a second pad 224, and a step 226 between the first pad 222 and the second pad 224. In the disclosure, a width and a length of the first pad 222 is less than a width and a length of an IC 230, and a width and a length of the second pad 224. During assembly, the IC 230 is fixed on the bonding pad 220 by adhesive 250 covering the step 226, a top surface of the first pad 222 and a bottom surface of the IC 230. The IC package assembly 200 can substantially perform the same function as the IC package assembly 100 described previously.

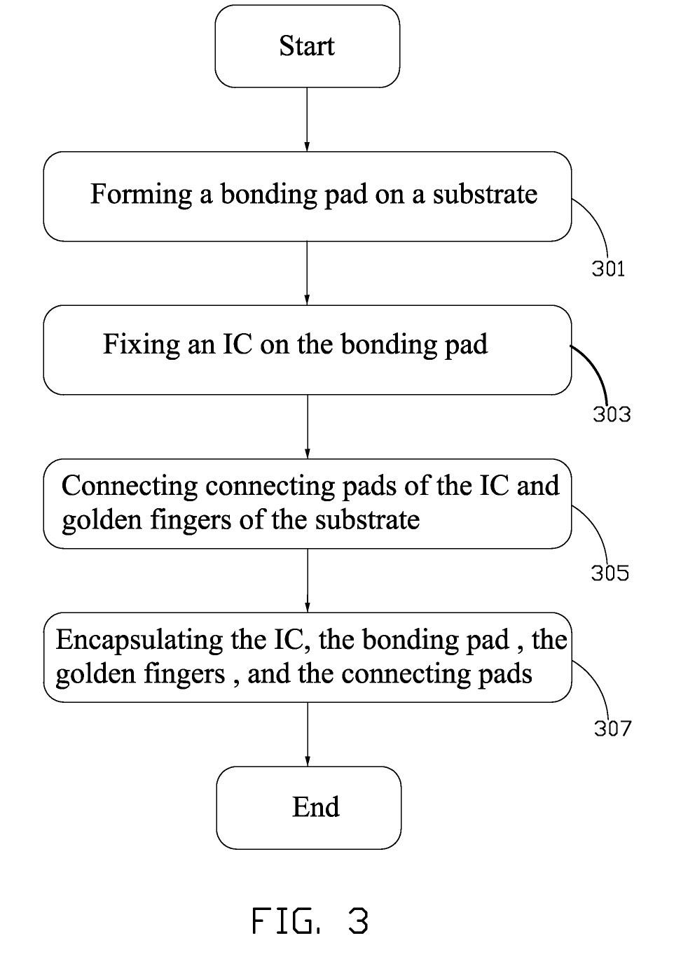

FIG. 3 is a flowchart of an IC package assembly packaging method in accordance with the present disclosure. The IC packaging method is operable to prevent the adhesive 50 or 250 from damage the IC 30 or 230.

In block S301, the bonding pad 20 or 220 is integrally formed with the substrate 10. In one example, the bonding pad 20 or 220 is plated on the substrate 100.

In block S303, the IC 30 or 230 is fixed on the bonding pad 20 or 220 by the adhesive 50 or 250.

In block S305, the plurality of bonding wires 40 electrically connect the plurality of connecting pads 32 and the plurality of golden fingers 12.

In block S307, the encapsulation 60 encapsulates the IC 30, the bonding pad 20, the plurality of connecting pads 32, and the plurality of bonding wires 40 therein.

While various embodiments and methods of the present disclosure have been described above, it should be understood that they have been presented by way of example only and not by way of limitation. Thus the breadth and scope of the present disclosure should not be limited by the above-described embodiments, but should be defined only in accordance with the following claims and their equivalents.

What is claimed is:

1. An integrated circuit (IC) package assembly comprising:
a substrate comprising a plurality of golden fingers;
a bonding pad integrally formed with the substrate;
an IC fixed on the bonding pad, the IC comprising a plurality of connecting pads, wherein a width and a length of the IC are greater than a width and a length of the bonding pad; and
a plurality of bonding wires electrically connecting the plurality of connecting pads to the plurality of golden fingers.

2. The integrated circuit package assembly of claim 1, wherein the bonding pad is plated on the substrate.

3. The integrated circuit package assembly of claim 2, wherein a thickness of the bonding pad is greater than a thickness of each of the plurality of golden fingers.

4. The integrated circuit package assembly of claim 2, wherein the bonding pad comprises a first pad, a second pad, and a step between the first pad and the second pad, wherein a width and a length of the first pad are less than a width and a length of the second pad.

5. The integrated circuit package assembly of claim 4, wherein a width and a length of the first pad are less than a width and a length of the IC.

6. The integrated circuit package assembly of claim 1, wherein a thickness of the IC is less than or equal to 50 μm.

7. An integrated circuit (IC) package assembly packaging method for fixing an IC comprising a plurality of connecting pads on a substrate comprising a plurality of golden fingers the method comprising:
integrally forming a bonding pad with the substrate;
fixing the IC on the bonding pad;
electrically connecting the plurality of connecting pads to the plurality of golden fingers; and
packaging the IC, the bonding pad, the plurality of connecting pads, and the plurality of golden fingers within an encapsulation;
wherein a width and a length of the IC are greater than a width and a length of the bonding pad.

8. The IC package assembly packaging method of claim 7, wherein a thickness of each of the plurality of golden fingers is less than a thickness of the bonding pad.

9. The IC package assembly packaging method of claim 7, wherein the bonding pad comprises a first pad, a second pad, and a step between the first pad and the second pad, and wherein a width and a length of the first pad are less than a width and a length of the second pad.

10. The IC package assembly packaging method of claim 9, wherein a width and a length of the first pad are less than a width and a length of the IC.
